(19) United States
(12) Patent Application Publication
(10) Pub. No.: US 2025/0273430 A1
(43) Pub. Date: Aug. 28, 2025

(54) RESONANT PHASE-CONTROLLED OSCILLATOR

(71) Applicant: Tokyo Electron Limited, Tokyo (JP)

(72) Inventors: Barton Lane, Austin, TX (US); Richard Brounley, Clearwater, FL (US); Merritt Funk, Austin, TX (US); Yohei Yamazawa, Taiwa-Cho (JP); Peter Lowell George Ventzek, Austin, TX (US)

(21) Appl. No.: 18/589,071

(22) Filed: Feb. 27, 2024

(51) Int. Cl. H01J 37/32

(52) U.S. Cl. CPC H01J 37/32146

(57) ABSTRACT

A resonant oscillator circuit includes an amplifier that includes a control input and a power output configured to deliver radio frequency (RF) power to a resonant load, and a feedback circuit. The feedback circuit includes a sensor coupled to the RF power, and a phase shifter coupled between the control input and the sensor. The sensor is configured to generate a feedback signal using the RF power. The phase shifter is configured to adjust a phase of the feedback signal to provide a conditioned feedback signal at the control input. The resonant oscillator circuit may be included as part of an RF system that includes a controller operatively coupled to the sensor and the phase shifter. The controller may be configured to control the phase shifter to adjust the phase of the feedback signal according to a sensor signal received from the sensor.

### TECHNICAL FIELD

The present invention relates generally to radio frequency power circuits, and, in particular embodiments, to systems, apparatuses, and methods for radio frequency power circuits that include a resonant phase-controlled oscillator circuit.

### BACKGROUND

Alternating current (AC) power sources (also known as AC power supplies) are designed to provide AC power to a load (such as an antenna or an electronic device) that alternates between a positive and a negative current at a desired frequency. While many AC power sources operate at relatively low frequencies, such as 50-60 Hz, AC power sources may also produce AC power at much higher frequencies. For example, one particular category of AC power source is a radio frequency (RF) power source, which produces AC power at a frequency in the RF portion of the electromagnetic spectrum, from about 20 kHz to about 300 GHz (RF power). A wide variety of electronic devices make use of RF power, such as communications equipment and industrial processing equipment.

Efficiently delivery of AC power, such as RF power, to a load can be difficult. For example, the load may include various components, discontinuities, structural features, etc. that can reflect some or all of the power back to the AC power source. The reflected power may then combine with the transmitted power to form standing waves. The difference between the total AC power provided by the AC power source and the net AC power delivered to the load may then be lost (e.g., due to component and circuit heating). To avoid this, the structure and circuitry of the load can be designed to minimize reflected power (e.g., by matching input and output impedance), such as at a particular frequency. For certain circuits, AC power coupling efficiency can be maximized when the AC power is delivered at a resonant frequency of the AC system where almost all of the delivered AC power is transmitted.

However, it is not always possible to deliver AC power at the resonant frequency. This is particularly true when the resonant frequency changes (e.g., because the impedance of the load changes) while the AC power is being delivered to the load. One way to adapt to changing impedance is to use adjustable (tunable) impedance matching circuits. Another way is to change the frequency of the AC power as the resonant frequency changes. Yet conventional solutions for both of these methods are relatively slow and are therefore unsuitable for AC systems where the resonant frequency of the load is rapidly changing.

One specific application where RF power sources are used is to provide RF power to semiconductor processing tools. For example, semiconductor processing tools may couple RF power to a process gas in order to generate plasma in a processing chamber. The plasma may be used to perform or enhance various semiconductor fabrication processes, such as deposition, etching, and others. When RF power is coupled to a processing chamber with no plasma, the processing chamber and associated structures designed to generate the plasma (e.g., antenna, source electrode, etc.) have a certain resonant frequency. Because plasma includes charge carriers (positive and negative species), the presence of the plasma in the processing chamber changes the resonant frequency and the efficiency of the RF power delivery is reduced.

Additionally, many plasma systems are pulsed plasma systems that deliver RF power to the processing chamber as a series of RF pulses, often inducing changes to the plasma properties that occur at timescales much faster than conventional solutions can adjust. This problem is compounded by the fact that the resonant frequency changes during each pulse, which meaning that problem persists throughout the entire pulsing process. That is, conventional solutions are unable to adjust the frequency of the applied RF power and/or the impedance of the circuit fast enough and are consequently unable to ever efficiently deliver RF power because the properties of the plasma, and hence the load impedance, are continually changing during the RF pulse. Moreover, this deficiency is present in any AC system where the resonant frequency of the load changes rapidly.

### SUMMARY

In accordance with and embodiment of the invention, a resonant oscillator circuit includes an amplifier that includes a control input and a power output configured to deliver radio frequency (RF) power to a resonant load, and a feedback circuit. The feedback circuit includes a sensor coupled to the RF power, and a phase shifter coupled between the control input and the sensor. The sensor is configured to generate a feedback signal using the RF power. The phase shifter is configured to adjust a phase of the feedback signal to provide a conditioned feedback signal at the control input.

In accordance with another embodiment of the invention, an RF system includes a resonant oscillator circuit that includes an amplifier with a control input and a power output configured to deliver RF power to a resonant load. The resonant oscillator circuit also includes a feedback circuit that includes a sensor coupled to the RF power, and a phase shifter coupled between the control input and the sensor. The sensor is configured to generate a feedback signal using the RF power. The RF system also includes a controller operatively coupled to the sensor and the phase shifter. The controller is configured to control the phase shifter to adjust a phase of the feedback signal according to a sensor signal received from the sensor to provide a conditioned feedback signal at the control input.

In accordance with still another embodiment of the invention, a plasma system includes a plasma chamber, an RF structure configured to generate a plasma in the plasma chamber using RF power, a resonant load, a transistor, a direct current (DC) power supply, and a feedback circuit. The resonant load includes the RF structure, the plasma chamber, and the plasma. The transistor includes a control input, a power input, and a power output configured to deliver the RF power to the resonant load. The DC power supply is coupled to the power input of the transistor. The feedback circuit includes a sensor coupled to the RF power, and a phase shifter coupled between the control input and the sensor. The sensor is configured to generate a feedback signal using the RF power. The phase shifter is configured to adjust a phase of the feedback signal to provide a conditioned feedback signal at the control input.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an example resonant oscillator circuit that includes a feedback circuit with a sensor coupled to RF power delivered at a power output of an amplifier and a phase shifter coupled between the sensor and a control input of the amplifier in accordance with embodiments of the invention;

FIG. 2 illustrates an example resonant oscillator circuit that includes a feedback circuit with both a phase shifter and an amplitude regulator in accordance with embodiments of the invention;

FIG. 3 illustrates an example resonant oscillator circuit that includes an amplifier with a DC power source coupled to a power input of a transistor through an RF choke as well as an optional DC bias and one or more optional impedance transformers in accordance with embodiments of the invention;

FIG. 4 illustrates an example resonant oscillator circuit that includes a feedback circuit with a sensor that is attached to a resonant load in accordance with embodiments of the invention;

FIG. 5 illustrates an example resonant oscillator circuit that includes a feedback circuit with a first sensor that is coupled in series with a transmission line between the power output of an amplifier and a resonant load as well as a second sensor that is attached to the resonant load in accordance with embodiments of the invention;

FIG. 6 illustrates an example RF system that includes a resonant oscillator circuit and a controller configured to send a phase control signal to a phase shifter of a feedback circuit of the resonant oscillator circuit and to receive a sensor signal from a sensor of the feedback circuit in accordance with embodiments of the invention;

FIG. 7 illustrates an example RF system that includes a resonant oscillator circuit and a controller configured to send an amplitude control signal to an amplitude regulator of a feedback circuit of the resonant oscillator circuit and to receive a sensor signal from a sensor of the feedback circuit in accordance with embodiments of the invention;

FIG. 8 illustrates an example RF system that includes a resonant oscillator circuit and a controller configured to send various control signals to components of an amplifier of the resonant oscillator circuit and to receive a sensor signal from a sensor of a feedback circuit of the resonant oscillator circuit in accordance with embodiments of the invention;

FIG. 9 illustrates an example plasma system that includes a feedback circuit coupled to RF power delivered to a resonant load that includes a plasma chamber, an RF structure configured to generate a plasma in the plasma chamber using the RF power, and the plasma where the feedback circuit includes a phase shifter in accordance with embodiments of the invention;

FIG. 10 illustrates an example plasma system where the RF structure is implemented as an upper electrode of a capacitively coupled plasma (CCP) plasma system in accordance with embodiments of the invention;

FIG. 11 illustrates an example plasma system where the RF structure is implemented as an RF antenna of an inductively coupled plasma (ICP) plasma system in accordance with embodiments of the invention; and

FIG. 12 illustrates an example method of adjusting the frequency of RF power applied to a resonant load in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

AC power sources, such as RF power sources, are used to supply AC power in a wide variety of applications including power distribution, communications equipment, industrial processing equipment, and others. One example of an application where RF power sources may be used is to supply RF power to a semiconductor processing tool. For example, an RF power source may be configured to couple RF power to a processing gas in order to generate plasma in a processing chamber of a semiconductor processing tool. The plasma can then be used to perform or enhance various semiconductor fabrication processes, such as deposition, etching, and others.

RF power may be delivered from an RF power source in the form of electromagnetic waves which propagate along a transmission line through RF elements and excite an antenna structure. The antenna structure may be configured to couple the RF power to some region or component of the system, such as plasma in a processing chamber, for example. The term antenna may be broadly understood in this context to be any structure designed to couple the RF power to another part of the system, and of course includes more specific definition of an antenna. The RF elements may include passive elements, such as capacitors and inductors, but can also include other elements including active elements in some cases.

Regardless of the specific application, efficient coupling of AC power (e.g., RF power) is desirable. For example, in a given AC circuit, some portion of the propagating electromagnetic waves may be reflected at various points in the AC circuit (i.e., dividing the electromagnetic waves from the total applied power into reflected waves and transmitted waves in some proportion). Such reflections often return power to the AC power source where it is dissipated as heat. That is, the reflected waves end up back at the AC power supply rather than continuing through the AC circuit. This is an undesirable result because more AC power must be delivered in order to couple the desired amount of power. Therefore, it is desirable to design AC systems so that the number and magnitude of reflections in the AC circuit are reduced.

While the difficulties in efficiently coupling AC power to a system apply to any resonant load that is changing rapidly in time (e.g., relative to the adjustment capabilities of the AC system), one specific example of such a rapidly changing resonant load is a semiconductor processing tool that employs pulsed RF power to generate plasma. For instance, the pulsed RF power may be delivered to a system with varying pulse amplitude, pulse frequency (i.e., the rate that the RF pulses are of repeated, in contrast to the RF frequency of the RF power itself), and duty cycle (the duration that the RF power is on within each pulse repetition period). Such RF power pulses produce repetitive transients in all plasma related quantities. Since the plasma forms an integral part of the RF circuit, a changing plasma presents a changing impedance to the RF system and can lead to increases in the reflected waves above an optimal configuration.

In the case that the plasma changes over time, in the absence of adjustments to the RF circuit, the RF power that is reflected from the load increases resulting in inconsistent power delivery to the plasma and/or dissipation of power as heat, such as in transistors (i.e., some of the delivered power is lost rather than coupled to the plasma). One conventional method of mitigating the fluctuations in reflected waves is to adjust the RF circuit as the impedance changes (e.g., by adjusting the frequency or by mechanically moving elements in the RF circuit). Clearly, the ability of such adjustments to prevent reflections is impacted by the speed that the adjustments are made. Specifically, the quicker the RF circuit is adjusted to match the changing impedance, the lower the reflected power will be. For pulsed plasma systems, the plasma is continuously changing. Therefore, adjustments need to be made on a timescale that is shorter than the timescale that the plasma changes (e.g., on the order of microseconds, such as about a 10 μs timescale, or about a 2 μs timescales, or even lower).

However, conventional mechanical adjustments are too slow to adjust to rapidly changing resonant loads, such as pulsed RF power. For example, RF pulse widths may be in the tens of microseconds, which, in the specific case of pulsed plasma systems, may cause changes to the plasma a 10 μs timescale (or lower). Yet, conventional mechanical adjustments are limited to ten to a hundred millisecond timescales. While conventionally adjusting the frequency of the RF power may be performed more quickly than mechanical adjustments, frequency adjustments are still limited to hundreds of microseconds which is at least an order of magnitude slower than short RF pulse widths and the timescale at which the plasma changes.

Therefore, an improved RF circuit, apparatus, and method that reduces the time necessary to optimize the power delivered to a resonant load is desirable. For example, it is desirable to quickly minimize reflected power so that RF power can be efficiently delivered to resonant loads that change rapidly in time (e.g., on the timescale of 10 μs, or about 2 μs or even faster).

In accordance with various embodiments herein described, the invention proposes a phase-controlled resonant oscillator that may be incorporated into an AC circuit (e.g., an RF circuit) coupled to a resonant load (e.g., including a resonant structure or a non-resonant structure that is part of a resonant RF circuit). One or more sensors in the AC circuit generate a feedback signal that may be used to adjust a base frequency of a control signal applied to a control input of an amplifier. The feedback signal is a function of the waveform of an output of the amplifier. The control signal is adjusted in order to match the resonant frequency of the resonant load, which may change (e.g., a rapidly changing resonant load, such as a pulsed RF system). Specifically, properties of the feedback signal, such as phase (e.g., using a phase shifter) and/or amplitude (e.g., with an amplitude regulator), and others, are adjusted to generate a conditioned feedback signal that is then provided as the control signal to the control input of the amplifier.

Various aspects of the feedback signal, such as the phase of the feedback signal, may be used to determine the base frequency. The amplifier may include an active element, such as a power transistor, and the base frequency may be applied to a control node of the active element, such as the gate of the power transistor. A direct current (DC) current source may be coupled to an input of the active element (e.g., a DC power supply electrically connected to the active element through an RF choke) and the control signal may be applied to the control node to control the flow of current through the active element (i.e., the control signal is related to the output of the active element, an example of which is the gate voltage of a power transistor being related to the drain current of the power transistor, or the DC power supply voltage that relates to the power delivered to the load). In various embodiments, the feedback signal is obtained using analog circuitry, which may have the advantage of enabling very fast adjustment of the base frequency (e.g., on the order of microseconds, or even faster).

A variety of conventional oscillator circuits have been designed to provide RF power to a load. However, conventional oscillator circuits typically use crystal oscillators (such as a quartz oscillator) and often do not include a feedback circuit. On the other hand, some conventional oscillator circuits do include a feedback circuit (sometimes referred to as feedback oscillator circuits). Feedback circuits with the ability to detect properties of the RF signal (such as relative phase of transmitted and reflected signals as well as their respective amplitudes) have been included in conventional RF power sources to allow impedance matching networks to respond to fluctuations in the impedance of a load. These conventional feedback circuits are unable to adjust quickly enough to efficiently couple power to rapidly changing loads. For example, conventional feedback circuits do not include various adjustment mechanisms present in the embodiment resonant oscillators described herein, such as a phase-shifter or an amplitude regulator.

The resonant oscillators described herein may be part of any AC circuit in an AC power source (e.g., an RF circuit in an RF power source) to advantageously reduce the necessary time to optimize delivery of RF power to a resonant load, such as a resonant load that changes rapidly in time. One particular area where the resonant oscillator may provide benefits are in pulsed RF systems due to rapid and repeated impedance transients. Pulsed RF systems are often used in semiconductor plasma systems and increasingly so in recent years. Conventional pulsed RF systems can adjust RF frequency on timescales of hundreds of microseconds and can adjust mechanical RF circuit elements on ten to a hundred millisecond timescales. Thus, during a portion of the pulse (which may be the entire pulse for many pulsed RF systems that use short pulses) the RF power delivery is not optimized and RF power is not coupled efficiently to the plasma. The resonant oscillators described herein may be advantageously utilized to optimize power delivery in any AC system with a resonant load that changes rapidly in time, such as virtually every application in the semiconductor industry that uses pulsed RF power.

It should also be noted that although conventional RF systems often utilize some combination of adjusting the frequency and mechanically adjusting RF circuit elements (e.g., mechanically adjustable capacitors), other adjustments, such as electrical adjustments could be possible. However, it can be difficult or impossible to achieve matching using electrical adjustments that is both accurate and affordable. Moreover, even advanced electrical adjustments may still operate on much longer timescales than tens of microseconds. The resonant oscillators described herein may advantageously allow for the compensation of the rapidly changing impedance at appropriately short timescales with low cost and complexity.

Additionally, instability is often encountered with resonant loads. For example, in the case of plasma systems, instability might arise from non-linear coupling of the RF waves and the plasma. In certain circumstances a positive feedback cycle may occur where a small decrease in the plasma density results in a corresponding small decrease in the RF power delivered to the system (e.g., because the coupling is poorer at lower density). This can create cascading effect as the decreased RF power leads to further decreased plasma density, in turn leading to decreased RF power delivery until the plasma extinguishes. Because in many systems the plasma is lost on timescales of tens of microseconds, the resonant oscillators described herein may be incorporated into such systems to correct for the decreased coupled power on a shorter timescale than the plasma changes and advantageously prevent instability. Furthermore, since the instability can occur to some extent in all resonant systems (limiting the parameter range of operation), the resonant oscillators described herein may combat this problem in any resonant system with the possible benefit of expanding the operational parameter range.

In the case of a plasma system where RF power used to generate plasma in a processing chamber, the plasma grows from near zero density to some initial low density within a few microseconds during striking and then continues to grow. The resonant frequency of the resonant load usually differs significantly between the empty chamber and the initial low-density plasma filled chamber (i.e., the plasma at the initial low density after striking). If the frequency of the RF power is preset to the empty chamber resonant frequency, the fields in the empty chamber are maximized and the initial breakdown (ionization of gases to generate plasma) occurs most easily. Therefore, deviation from the empty chamber resonant frequency decreases the fields in the empty chamber and plasma is generated less easily (i.e., less efficiently). If the frequency of the RF power is not set close enough to the empty chamber resonant frequency, then ignition of the plasma may not occur at all (or the power required to generate the plasma may be impractical). This may be particularly important at low chamber pressures where striking is more difficult to achieve.

Once a low-density plasma is achieved, the resonant frequency of the plasma system changes and the initial empty chamber resonant frequency is no longer optimal (because of the low-density plasma). As a result, the RF power delivered to the plasma at the empty chamber resonant frequency may be insufficient to allow it to grow (or at least the RF power may be inefficiently delivered requiring higher power to achieve the same effect while losing power to heat generated in components of the RF circuit). Since conventional plasma systems are not capable of adjusting the RF frequency quickly enough, a compromise RF frequency in between the optional striking frequency and the optimal plasma growth frequency may be chosen. The difference between the compromise RF frequency and the empty chamber resonant frequency leads to a degradation in the ability to strike at low pressure.

Advantageously, the resonant oscillators described herein can adjust the RF frequency sufficiently quickly to maintain an optimum frequency throughout the entire striking transient. That is, the empty chamber resonant frequency may be used for striking and the frequency may be adjusted fast enough as the density of the plasma increases to match the resonant frequency of the load (now including the plasma) as the plasma density changes enabling striking at lower pressures and preventing premature extinguishing of the plasma after striking due to poorly coupled power.

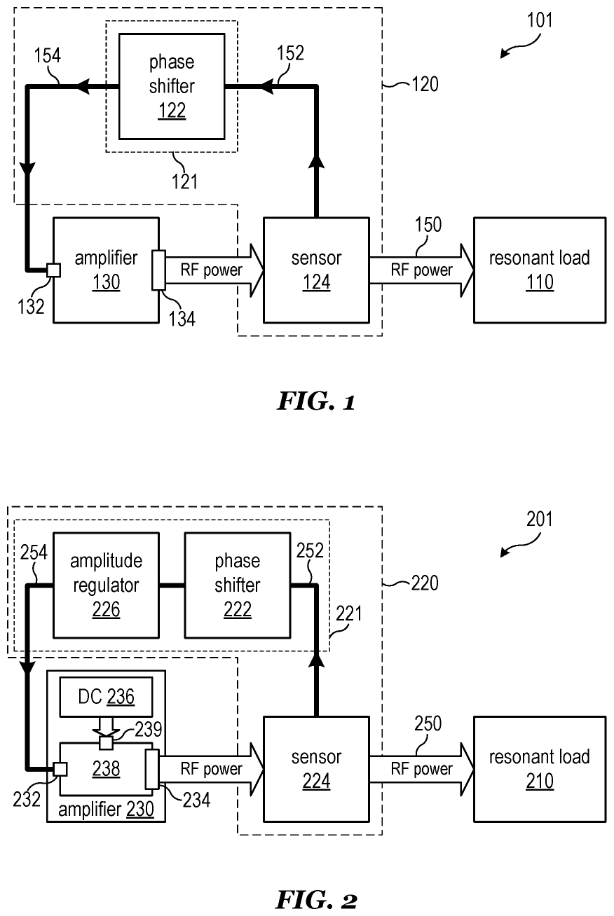

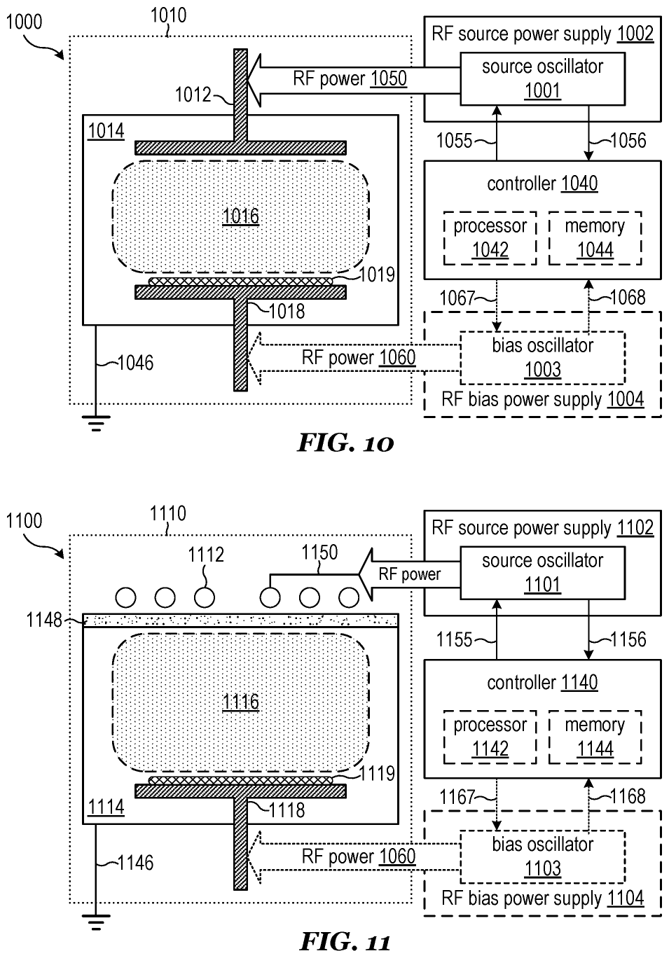

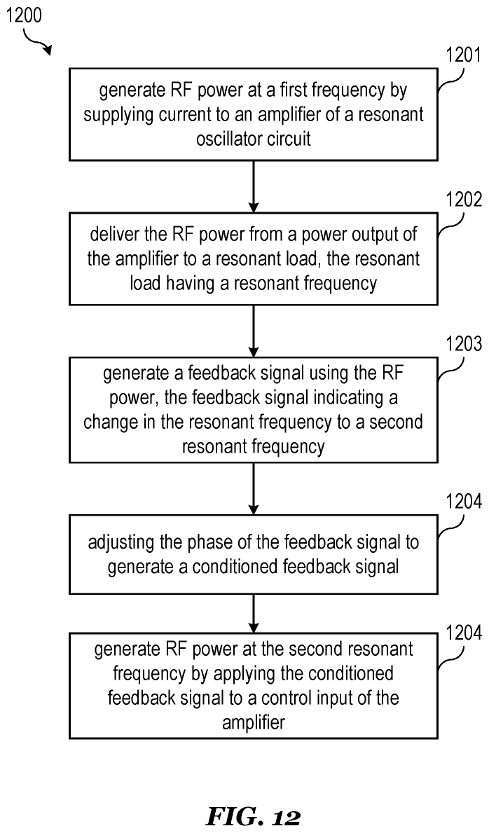

Embodiments provided below describe various resonant oscillator circuits, and in particular, systems, apparatuses, and methods that include resonant oscillator circuits with a feedback circuit that includes a phase shifter. The following description describes the embodiments. FIG. 1 is used to describe an example resonant oscillator circuit. Four more example resonant oscillator circuits are described using FIGS. 2-5. Three example RF systems that include resonant oscillator circuits are described using FIGS. 6-8. An example plasma system that includes one or more resonant oscillator circuits is described using FIG. 9 while an example CCP plasma system and an example ICP plasma system are described using FIGS. 10 and 11 respectively. An example method of adjusting the frequency of RF power applied to a resonant load using a resonant oscillator circuit is described using FIG. 12.

FIG. 1 illustrates an example resonant oscillator circuit that includes a feedback circuit with a sensor coupled to RF power delivered at a power output of an amplifier and a phase shifter coupled between the sensor and a control input of the amplifier in accordance with embodiments of the invention. It should be noted that while here and in the following RF power is used as a specific example, it is recognized that the principles involved apply equally well to AC signals of any frequency.

Referring to FIG. 1, a resonant oscillator circuit 101 includes a feedback circuit 120 and an amplifier 130. The resonant oscillator circuit 101 is configured to deliver RF power 150 to a resonant load 110 from a power output 134 of the amplifier 130. The feedback circuit 120 includes a sensor 124 that is coupled to the RF power 150 in such a way as to generate a feedback signal 152 that is a function of the waveform of the RF power 150 (i.e., the sensor 124 uses the RF power 150 to generate the feedback signal 152). The feedback signal 152 is provided to feedback conditioning components 121 that alter one or more properties of the feedback signal 152 to generate a conditioned feedback signal 154. The amplifier 130 has a control input 132 that is used to control the properties of the RF power 150 provided at the power output 134.

The feedback conditioning components 121 may include various components, but at least includes a phase shifter 122 (i.e., a fixed phase shifter or a variable phase shifter) that is configured to modify the phase of the feedback signal 152. The phase adjustment that generates the conditioned feedback signal 154 changes the resonant frequency of the resonant oscillator circuit 101. For example, the resonant oscillator circuit 101 may operate as a feedback oscillator circuit that converges to a resonant frequency based on the structure and components of the resonant oscillator circuit 101 that determines the frequency of the RF power 150. By adjusting the phase of the feedback signal 152, the resonant frequency of the resonant oscillator circuit 101 can be changed thereby also changing the frequency of the RF power 150. In this way, changes to the impedance of the resonant load 110 (e.g., the resonant frequency of the resonant load 110) can be counteracted by delivering the RF power 150 to the resonant load 110 at the new resonant frequency of the resonant load 110.

The feedback signal 152 may be generally described as a superposition of sinusoidal waves (e.g., at discrete multiples of some fundamental frequency as a Fourier decomposition). That is, each Fourier component has an amplitude and a phase relative to the fundamental. The conditioned feedback signal 154 is generated by adjusting the amplitude and/or the phase of one or more of the Fourier components of the feedback signal 152. This may be performed using various circuit components, including active circuit elements, such as one or more amplifiers, or passive circuit elements, such as transmission lines, passive filters, etc.

In some applications, additional elements may be included in the feedback circuit 120. For example, an amplitude regulator may also be included in the feedback conditioning components 121 to adjust the amplitude of the feedback signal 152. Another example of a possible additional element is a frequency shifter that is configured to manipulate the frequency of the feedback signal 152. For example, it may be desirable to manipulate the frequency of the feedback signal 152 during various times, such as at the beginning of RF pulses (e.g., to get the pulse started as fast as possible). One possible implementation of a frequency shifter may be configured to inject a certain frequency into the feedback circuit. Another possible implementation may be to mix in another frequency into the feedback circuit. Software defined radio frequencies may also be used.

The feedback conditioning components 121 and in particular the phase shifter 122 may be configured to adjust the resonant frequency of the resonant oscillator circuit 101 at sufficiently short timescale to allow efficient coupling of the RF power 150 to a rapidly changing resonant load 110. For example, the phase shifter 122 may be an analog phase shifter in an embodiment. The analog phase shifter may be controlled by setting various operating parameters and the phase adjustment of the analog phase shifter may be on a shorter timescale than the timescale that the impedance of the resonant load 110 changes. In various embodiments, the feedback conditioning components 121 are configured to change the resonant frequency on a timescale at or shorter than about tens of microseconds. In some embodiments, the feedback conditioning components 121 are configured to change the resonant frequency on a timescale at or shorter than about 10 μs, and on a timescale at or shorter than about 2 μs in one embodiment.

The resonant oscillator circuit 101 may be considered a resonant phase-controlled oscillator because of the ability to alter the frequency of the RF power 150 using the feedback circuit 120 and the phase shifter 122. The resonant oscillator circuit 101 may have a frequency bandwidth within which the frequency of the RF power 150 changes that may depend on the specific structure and components of the resonant oscillator circuit 101 (including the characteristics of the resonant load 110, which may change). That is, the frequencies that may be delivered by the resonant oscillator circuit 101 are bounded by various properties of the circuit itself. The feedback circuit 120 with the phase shifter 122 is configured to generate the conditioned feedback signal 154 in order to expand the ability of the resonant oscillator circuit 101 to adjust the frequency of the RF power 150 in response to the changing impedance of the resonant load 110. In various embodiments, the conditioned feedback signal 154 is configured to adjust the resonant frequency of the resonant oscillator circuit 101 within a frequency bandwidth less than about ten percent of the base resonant frequency (i.e., the base resonant frequency is the resonant frequency of the resonant oscillator circuit 101 if the phase shifter 122 does not alter the phase of the feedback signal 152).

The resonant load 110 may be any resonant system. One example of a resonant system may be a resonant conductor, which resonates at a certain frequency due to its geometry (e.g., a resonant antenna, such as used to generate an ICP plasma). Another example of a resonant system is a non-resonant conductor (e.g., any conductor, one example of which would be an electrode, such as used to generate a CCP plasma, and that can also sometimes be referred to as an antenna) that is coupled to other lumped circuit elements (e.g., capacitors, inductors, etc.) so that the combination becomes a resonant system. In either case, the fields in the antenna structure may be maximized when the applied frequency is equal to the resonant frequency. In the case of a plasma system, the combined system of the resonant or non-resonant structure, the processing chamber, and the plasma may be the resonant load 110.

However, as already mentioned, the resonant frequency of the resonant load 110 may depend on more than the resonant system itself. For example, in a plasma system, the resonant frequency may depend on the plasma properties, such as the plasma density (but also including other properties, such as the size and shape of the plasma). Thus, when RF power is applied to generate a plasma and the plasma density grows from approximately zero to some substantially constant value, the resonant frequency of the resonant load is changing. This is especially dramatic in pulsed systems, as the growth of the plasma density takes place on timescales of tens of microseconds while the RF pulses may be applied with comparative duration and at high pulse frequencies. This highlights the potential advantage of being able to adjust the drive frequency at similar or faster timescales (which is not possible with conventional systems).

While the capability of adjusting the phase of the feedback signal 152 dynamically over the course of a pulse may or may not be necessary, depending on the application, it may be a significant advantage in pulsed plasma systems where the plasma changes the impedance of the resonant load 110 at timescales that are shorter than the pulse width. For this reason, the resonant oscillator circuit 101 would advantageously increase the coupling efficiency either way, but may have the benefit of achieving optimal coupling when the phase can be changed faster than a pulse.

The resonant load 110 may include various components that make up an RF circuit, such as a resonant structure. For example, in the specific case of a plasma system, the resonant structure may be a chamber antenna that is configured to couple RF power to a plasma. The chamber antenna may be the part of the RF circuit of the resonant load 110 that is adjacent to the plasma. The chamber antenna may include current carrying elements that are configured to produce time-varying magnetic fields and/or metal surfaces that are configured to accumulate charge due to RF fields and the accumulated charges may produce electric fields. Both the magnetic fields and the electric fields may then penetrate into the plasma, heating the plasma and affecting plasma properties, such as electrical potential. Coupled magnetic fields may be referred to as inductive coupling while coupled electric fields may be referred to as capacitive coupling, although both magnetic and electric fields are typically present in a given configuration.

The feedback circuit 120 is configured to generate feedback signal 152 using the sensor 124 by picking up the RF signal output by the amplifier 130 (the RF power 150 from the power output 134 that is also delivered to the resonant load 110). The feedback signal 152 is then routed back to the control input 132 of the amplifier 130. Specifically, the feedback signal 152 is modified by the phase shifter 122 (and other components in some embodiments) to generate the conditioned feedback signal 154 which is applied directly to the control input 132. The control input 132 may be the gate of a transistor (e.g., the conditioned feedback signal 154 may operate directly on the gate of the transistor). In other embodiments, other circuitry of the amplifier 130 (whether active or passive) may be included between the control input 132 and a transistor, such as logic circuitry, a microcontroller, etc.

In order for the resonant oscillator circuit 101 to operate as an oscillator, the phase of the conditioned feedback signal 154 may be constrained by the relationship between the control input 132 and the power output 134 of the amplifier 130. That is, the amplifier 130 (e.g., including a transistor) has its own operating characteristics that may define acceptable parameter values at the control input 132 that will achieve the desired amplifier output. For example, with some transistor types, when the voltage at the control input 132 of the amplifier 130 is higher, the current at the power output 134 will also be higher. Correspondingly, when the voltage at the control input 132 of the amplifier 130 is low, the current at the power output 134 will also be lower and eventually be cut off entirely.

In the absence of the phase shifter 122, the resonant oscillator circuit 101 has its own resonant frequency that is dependent on the various components in the feedback circuit 120, but also dependent on the phase at the control input 132. As a result, changing the phase of the feedback signal 152 using the phase shifter 122 also changes the resonant frequency of the resonant oscillator circuit 101.

The feedback circuit 120 may include more than one sensor producing signals. These signals may be combined in the phase shifter 122 (or in a separate combiner unit) to produce a single signal with a phase that has been shifted relative to a reference phase. The reference phase may be the phase of the signal from the sensor 124, or may be the phase of the signal from a predetermined one of the sensors if there are multiple. Other properties of the single or combined feedback signal, such as amplitude, may also be adjusted before providing the conditioned feedback signal 154 at the control input 132 of the amplifier 130.

The phase shifter 122 may be implemented in various ways. For example, the phase shifter 122 may be mechanical or electronic. A mechanical phase shifter may be configured to mechanically adjust the length of the transmission line through which the feedback signal 152 propagates to introduce a phase delay (e.g., because of the finite propagation speed of the feedback signal 152). In contrast, an electronic phase shifter may be configured to use active electronic elements to modify the phase, such as by exploiting the fact that reactive elements like capacitors and inductors can change the phase of the feedback signal 152.

The amplifier 130 is configured to output current (e.g., from a DC power source, such as a DC current source) with a waveform that is based on a signal received at the control input 132. In various embodiments, the amplifier 130 includes one or more transistors with a power input node electrically coupled to a DC power source and a power output node (e.g., power output 134) coupled to the resonant load 110. The DC power source may include a current source that maintains a constant voltage (or constant current) and an RF choke configured to ensure that the current from the DC power source is not influenced by RF fluctuations. For example, the RF choke may be implemented using some combination of inductors and capacitors. A control node (e.g., a gate) of the one or more transistors may be coupled to the conditioned feedback signal 154, which functions as a control signal.

The sensor 124 (e.g., a current sensor, voltage sensor, a directional coupler, etc.) is configured to generate a signal (i.e., the feedback signal 152) that is dependent on a property of the output signal of the amplifier 130 (i.e., the RF power 150 being supplied to the resonant load 110). For example, the sensor 124 may be a passive element, such as a pickup coil (for generating a current proportional to the current of the output signal). In one implementation, the sensor 124 may be an antenna sensor (e.g., near or on an RF structure of the resonant load 110, such as an antenna or an electrode, or on the processing chamber of a plasma system) that is configured to react to the output signal in the resonant load. Other sensors may also be included, such as sensors configured to measure reflected power, etc.

The sensor 124 may be any RF circuit element configured to couple to electromagnetic waves in a proximate RF circuit element, such as a transmission line, current carrying element, metallic structures immersed in a surrounding electromagnetic field environment, etc. The sensor 124 may be designed so that some of the electromagnetic wave energy is coupled to another lower level electromagnetic wave which then propagates as a signal to a device which senses its level. The sensor 124 may be purely passive, may contain active elements, such as transistors and amplifiers, or may be some combination thereof. In some embodiments, the sensor 124 is sensitive to the time-varying magnetic field produced by a time-varying current (i.e., a current “pickup” or current sensor). In other embodiments, the sensor 124 is sensitive to the time-varying electric field (i.e., a voltage “pickup” or voltage sensor). Of course, the sensor 124 may also be sensitive to some combination of time-varying electric and magnetic fields.

For example, the sensor may be configured so that electromagnetic waves moving in one direction on a transmission line are directed to one output port while waves moving in the opposite direction are directed to another output port; such a sensor may be called a “directional coupler”. In general, sensors may be configured to be sensitive to electromagnetic waves and respond physically to the electromagnetic waves on a timescale that is less than the wave oscillation period. That is, it is desirable for a sensor to be able to detect information as to the frequency, amplitude, and/or phase of the electromagnetic wave and relay that information electrically. For example, the sensor may relay this information in the form of a lower amplitude electromagnetic wave whose amplitude and phase are related to the amplitude and phase of the measured electromagnetic fields or it may relay the information as the amplitude and phase by other electrical means, whether analog or digital. This information, which may be modified by other circuitry, can then be used to regenerate the feedback signal 152 before it is applied as the conditioned feedback signal 154 to the control input 132 (e.g., a transistor control input port).

The amplifier 130 may have various components. For example, the amplifier 130 may include one or more active elements (e.g., power transistors, such as a field-effect transistor (FET), bipolar junction transistor (BJT), or other elements such as thyristors, etc.), a DC power source, a DC bias source, input and/or output impedance transformers, and others.

The sensor 124 may be placed in various locations in the resonant oscillator circuit 101 or in the resonant load 110. In one embodiment, the sensor 124 is placed in the transmission (power) line carrying the RF power 150 between the amplifier 130 and the resonant load 110. In this location, the sensor 124 may be configured to be sensitive to the fields in the transmission line which include the forward (transmitted) electromagnetic waves from the amplifier 130 and the reflected waves from resonant load 110. The sensor 124 may also be placed inside or attached to an RF structure in the resonant load 110. In this location, the sensor 124 may be configured to be directly sensitive to the electromagnetic fields of the resonant load. There may be advantages to having sensors in specific or multiple locations in the feedback circuit 120. For example, having one or more sensors in the resonant load may be able to track signal properties over a larger frequency range. However, the desired capabilities of the sensors and sensor locations may depend on the needs of a given application.

FIG. 2 illustrates an example resonant oscillator circuit that includes a feedback circuit with both a phase shifter and an amplitude regulator in accordance with embodiments of the invention. The resonant oscillator circuit of FIG. 2 may be a specific implementation of other resonant oscillator circuits described herein such as the resonant oscillator circuit of FIG. 1, for example. Similarly labeled elements may be as previously described.

Referring to FIG. 2, a resonant oscillator circuit 201 includes a feedback circuit 220 and an amplifier 230. It should be noted that here and in the following a convention has been adopted for brevity and clarity wherein elements adhering to the pattern [x01] where ‘x’ is the figure number may be related implementations of a resonant oscillator circuit in various embodiments. For example, the resonant oscillator circuit 201 may be similar to the resonant oscillator circuit 101 except as otherwise stated. An analogous convention has also been adopted for other elements as made clear by the use of similar terms in conjunction with the aforementioned numbering system.

The resonant oscillator circuit 201 is configured to deliver RF power 250 to a resonant load 210 from a power output 234 of the amplifier 230 using a sensor 224 coupled to the RF power 250 in such a way as to generate a feedback signal 252 according to the RF power 250. Feedback conditioning components 221 include a phase shifter 222 and modify one or more properties of the feedback signal 252 to generate a conditioned feedback signal 254, which is provided to a control input 232 of the amplifier 230. The amplifier 230 is also shown with two example internal components: a DC power supply 236 configured to deliver DC power to an active element 238 (e.g., one or more transistors) at a power input 239. The control input 232 may be control node of the active element 238 (e.g., a gate or gates of the transistor(s)) and may control the flow of current from the DC power supply 236 through the active element 238 to the power output 234.

In the specific example of the resonant oscillator circuit 201, an amplitude regulator 226 is also be included in the feedback circuit 220. The amplitude regulator 226 is configured to provide additional control over the behavior of the amplifier 230. For example, the amplitude regulator 226 may be a preamplifier whose amplification is adjusted in order to produce a certain amplitude for the feedback signal 252 that will be applied to the control input 232 (e.g., a transistor gate). One purpose of controlling the input signal level may be to control the amplifier output power. Another purpose of controlling the input signal level may be to increase the efficiency of the amplifier (e.g., allowing transistor(s) to operate in class D mode, as opposed to class A mode). Still another purpose may be to protect the amplifier input from over-voltages.

In various embodiments, the amplitude may be adjusted using analog techniques, such as by using the RF amplitude of the amplifier output as an input or by comparison to a fixed signal level. The amplitude may also be adjusted using analog techniques in combination with control signals (e.g., from the controller) which may be analog or digital.

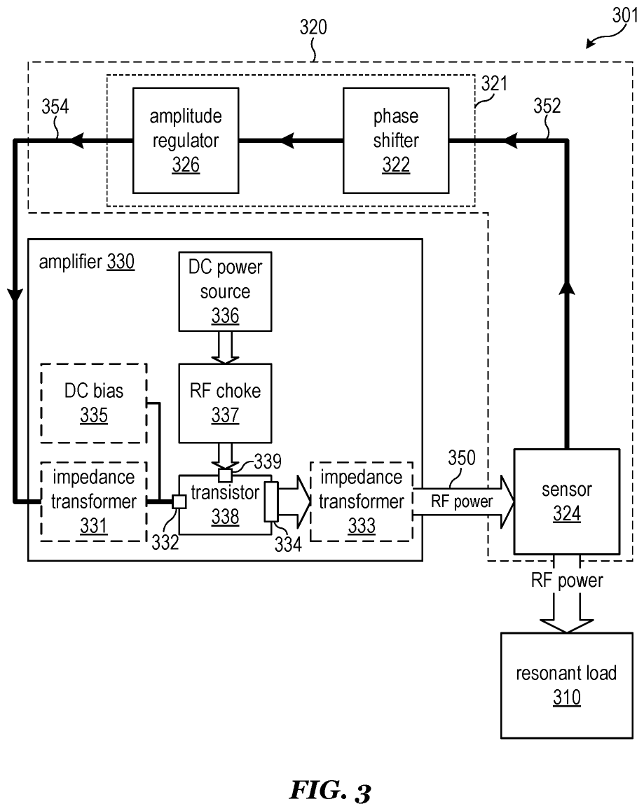

FIG. 3 illustrates an example resonant oscillator circuit that includes an amplifier with a DC power source coupled to a power input of a transistor through an RF choke as well as an optional DC bias and one or more optional impedance transformers in accordance with embodiments of the invention. The resonant oscillator circuit of FIG. 3 may be a specific implementation of other resonant oscillator circuits described herein such as the resonant oscillator circuit of FIG. 1, for example. Similarly labeled elements may be as previously described.

Referring to FIG. 3, a resonant oscillator circuit 301 includes a feedback circuit 320 and an amplifier 330. The resonant oscillator circuit 301 is configured to deliver RF power 350 to a resonant load 310 from a power output 334 of the amplifier 330 using a sensor 324 coupled to the RF power 350 in such a way as to generate a feedback signal 352 according to the RF power 350. Feedback conditioning components 321 (here including a phase shifter 322 and an amplitude regulator 326, but may have different configurations) modify one or more properties of the feedback signal 352 to generate a conditioned feedback signal 354, which is provided to a control input 332 of the amplifier 330.

The amplifier 330 may have various components. For example, the amplifier 330 may include one or more active elements (e.g., power transistors, such as a FET, a BJT, or other elements such as thyristors, etc.). In this specific example, the amplifier 330 includes a transistor 338 with the control input 332 being the gate of the transistor 338. Of course, the transistor 338 may be one of a pair of transistors (or many transistors). A DC power supply may be implemented as a DC power source 336 (such as a DC current source) coupled to a power input 339 of the transistor 338 through an RF choke 337. A DC bias 335 may be coupled to the control input 332 and facilitate control over the voltage at the control input 332. For example, the DC bias 335 may be configured to increase the voltage at the control input 332 to exceed a saturation threshold of the amplifier 330 (i.e., the transistor 338 and other transistors if an array of transistors is included) so that the amplifier 330 operates as a class D amplifier.

One or more impedance transformers (shown here as optional parts of the amplifier 330) may also be included in the resonant oscillator circuit 301. For example, an optional input impedance transformer 331 may be included between the feedback conditioning components 321 and the control input 332 to control the impedance of the control signal (i.e., the conditioned feedback signal 354). Similarly, an optional output impedance transformer 333 may be included after the power output 334 to control the impedance of the RF power 350. Impedance transformers may be passive circuit elements that transform the impedance (e.g., collections of inductors, capacitors and or transformers). In various embodiments some or all of the impedance transformers included in the resonant oscillator circuit 301 may have flat frequency characteristics.

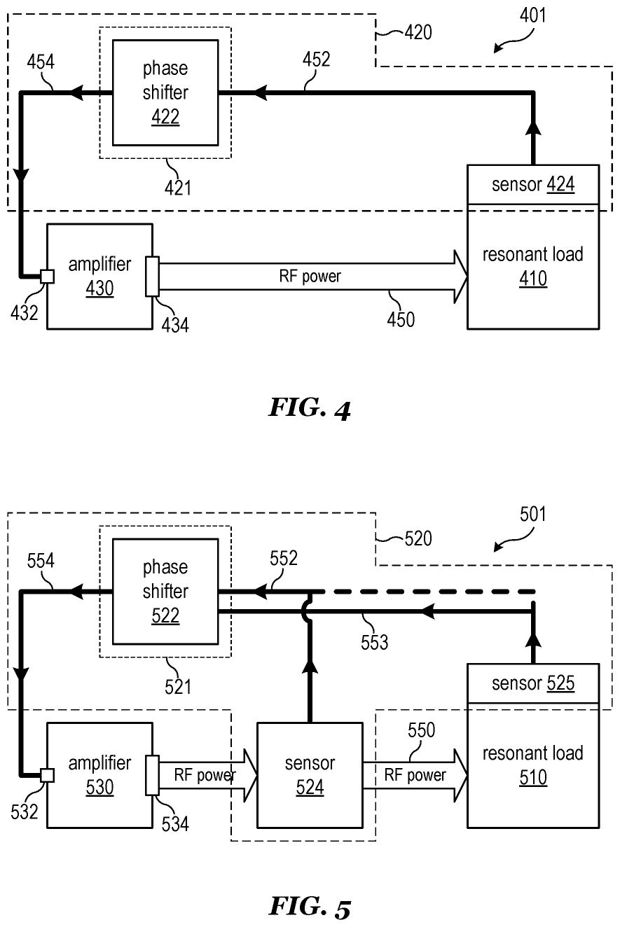

FIG. 4 illustrates an example resonant oscillator circuit that includes a feedback circuit with a sensor that is attached to a resonant load in accordance with embodiments of the invention. The resonant oscillator circuit of FIG. 4 may be a specific implementation of other resonant oscillator circuits described herein such as the resonant oscillator circuit of FIG. 1, for example. Similarly labeled elements may be as previously described.

Referring to FIG. 4, a resonant oscillator circuit 401 includes a feedback circuit 420 and an amplifier 430. The resonant oscillator circuit 401 is configured to deliver RF power 450 to a resonant load 410 from a power output 434 of the amplifier 430 using a sensor 424 coupled to the RF power 450 in such a way as to generate a feedback signal 452 according to the RF power 450. Feedback conditioning components 421 include a phase shifter 422 and modify one or more properties of the feedback signal 452 to generate a conditioned feedback signal 454, which is provided to a control input 432 of the amplifier 430.

In contrast to other resonant oscillator circuits discussed thus far, the sensor 424 is shown in this specific example to be attached to the resonant load 410 (e.g., attached to a structure (resonant or non-resonant) of the resonant load 410, such as an RF antenna, source electrode, attached to a processing chamber such as a plasma chamber, etc.). Of course, other positions may also be possible and other sensors may also be included, as illustrated in the following figure.

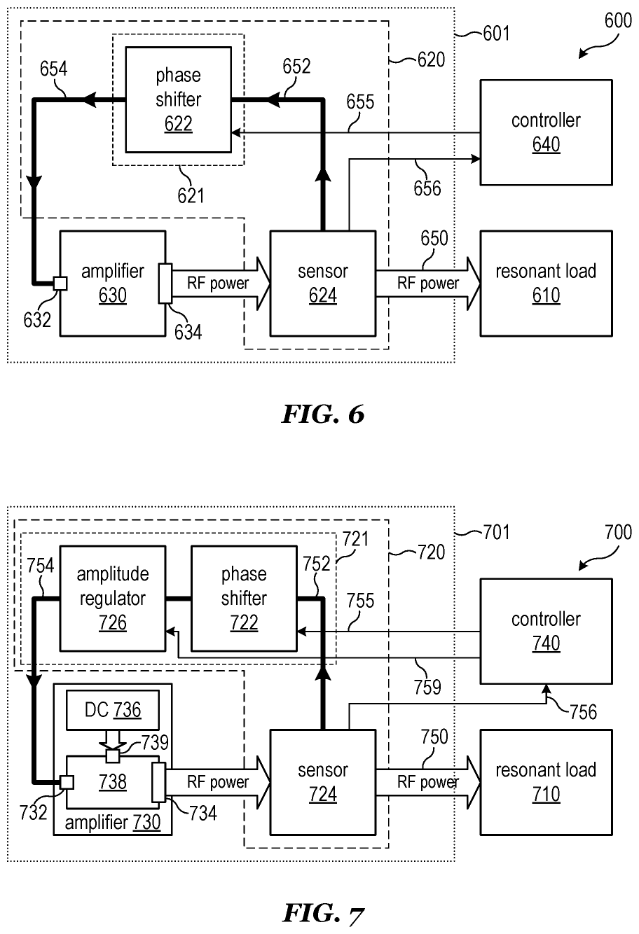

FIG. 5 illustrates an example resonant oscillator circuit that includes a feedback circuit with a first sensor that is coupled in series with a transmission line between the power output of an amplifier and a resonant load as well as a second sensor that is attached to the resonant load in accordance with embodiments of the invention. The resonant oscillator circuit of FIG. 5 may be a specific implementation of other resonant oscillator circuits described herein such as the resonant oscillator circuit of FIG. 1, for example. Similarly labeled elements may be as previously described.

Referring to FIG. 5, a resonant oscillator circuit 501 includes a feedback circuit 520 and an amplifier 530. The resonant oscillator circuit 501 is configured to deliver RF power through a transmission line 550 to a resonant load 510 from a power output 534 of the amplifier 530 using a first sensor 524 coupled to the RF power (e.g., in series with the transmission line 550) in such a way as to generate a first feedback signal 552 according to the RF power. Feedback conditioning components 521 include a phase shifter 522 and modify one or more properties of the first feedback signal 552 to generate a conditioned feedback signal 554, which is provided to a control input 532 of the amplifier 530.

In the specific example of the resonant oscillator circuit 501, a second sensor 525 is also included, shown as attached to the resonant load 510 (similar to the sensor 424). The second sensor 525 may be configured to generate its own second feedback signal 553 that may be provided to the feedback conditioning components 521 separately from the first feedback signal 552 (as shown) or may be combined before the feedback conditioning components 521. Internally, the first feedback signal 552 and the second feedback signal 553 may be separately modified or a combined signal may be modified by and of the feedback conditioning components 521. Clearly, although two sensors are shown in this specific example, more sensors may be included, whether in different locations in the resonant oscillator circuit 501 or in similar locations, but different positions (e.g., different part of the transmission line 550, different region of the resonant load 510, etc.).

FIG. 6 illustrates an example RF system that includes a resonant oscillator circuit and a controller configured to send a phase control signal to a phase shifter of a feedback circuit of the resonant oscillator circuit and to receive a sensor signal from a sensor of the feedback circuit in accordance with embodiments of the invention. The RF system of FIG. 6 may include any of the resonant oscillator circuits described herein, such as the resonant oscillator circuit of FIG. 1, for example. Similarly labeled elements may be as previously described.

Referring to FIG. 6, an RF system 600 includes a resonant oscillator circuit 601 that includes a feedback circuit 620 and an amplifier 630. The resonant oscillator circuit 601 is configured to deliver RF power 650 to a resonant load 610 from a power output 634 of the amplifier 630 using a sensor 624 coupled to the RF power 650 in such a way as to generate a feedback signal 652 according to the RF power 650. Feedback conditioning components 621, including a phase shifter 622, modify one or more properties of the feedback signal 652 to generate a conditioned feedback signal 654, which is provided to a control input 632 of the amplifier 630.

In addition to the resonant oscillator circuit 601, the RF system 600 also includes a controller 640. The controller 640 is configured to control various elements in the resonant oscillator circuit 601. For example, the controller 640 is configured to control the phase shifter 622 using a phase control signal 655. That is, the phase of the conditioned feedback signal 654 is controlled by the phase shifter 622, which in turn is controlled by the controller 640 (e.g., directly or through setting operating parameters). Of course, when other elements are present in the resonant oscillator circuit 601 (such as in the feedback conditioning components 621 or the amplifier 630), the controller 640 may be configured to control some or all of the additional controllable elements.

The controller 640 may be configured to receive a sensor signal 656 from the sensor 624. For example, the sensor signal 656 may provide information to the controller 640 about the properties of the RF power 650. This information may then be used by the controller 640 to appropriately control the phase shifter 622 using the phase control signal 655 (as well as other elements when present). In various embodiments, the controller 640 controls the phase adjustment of the phase shifter 622 according to the sensor signal 656. The controller 640 may have inputs from multiple sensors as well as from outside the RF system 600 (e.g., to allow the configuration of the RF system 600 to be determined using set points).

In addition to the sensors already discussed, the sensor inputs to the controller 640 may include sensors that reflect parameters of the RF system 600 such as its oscillation frequency, thermal data, electromagnetic field strengths, forward and backward wave strengths, as well as further sensors, such as pressure sensors, photodiodes, plasma optical emission spectrometers, and microwave interferometers, and also external tool settings (e.g., from a recipe for a process), such as gas valve settings, settings related to pulse parameters, total recipe time duration, etc.

The controller 640 may include digital elements and analog elements. For example, the controller 640 may control the controllable elements of the resonant oscillator circuit 601 using an analog circuit, through a digital circuit (which may reference stored data and numerical algorithms), or a combination of the two. Such data and numerical algorithms may be changed externally and/or may modify themselves on the basis of data acquired by the controller 640 based on its sensors. In some cases, using analog elements may enhance the speed of the controller 640 (which, as already discussed, may be important for maintaining optimal power delivery in rapidly changing resonant systems). The analog elements may then themselves be controlled using digital elements, such as by using digital elements to set operating parameters of the analog elements. The phase shifter 622 may combine signals from different sensors (sensor 624 and others) to produce a single signal with a particular phase shift, and the function for combining the several signals may also be controllable by the controller 640.

FIG. 7 illustrates an example RF system that includes a resonant oscillator circuit and a controller configured to send an amplitude control signal to an amplitude regulator of a feedback circuit of the resonant oscillator circuit and to receive a sensor signal from a sensor of the feedback circuit in accordance with embodiments of the invention. The RF system of FIG. 7 may be a specific implementation of other RF systems described herein such as the RF system of FIG. 6, for example. Similarly labeled elements may be as previously described.

Referring to FIG. 7, an RF system 700 includes a resonant oscillator circuit 701 that includes a feedback circuit 720 and an amplifier 730. The resonant oscillator circuit 701 is configured to deliver RF power 750 to a resonant load 710 from a power output 734 of the amplifier 730 using a sensor 724 coupled to the RF power 750 in such a way as to generate a feedback signal 752 according to the RF power 750. Feedback conditioning components 721, which include a phase shifter 722 and an amplitude regulator 726, modify one or more properties of the feedback signal 752 to generate a conditioned feedback signal 754, which is provided to a control input 732 of the amplifier 730. The amplifier 730 includes a DC power supply 736 that is configured to deliver DC power at a power input 739 of an active element 738.

Similar to the preceding RF system, the RF system 700 also includes a controller 740 that is configured to receive a sensor signal 756 from the sensor 724 and control the phase shifter 722 using a phase control signal 755. Additionally, since the amplitude regulator 726 is also included in the feedback conditioning components 721, the controller 740 is further configured to control the amplitude regulator 726 using an amplitude control signal 759.

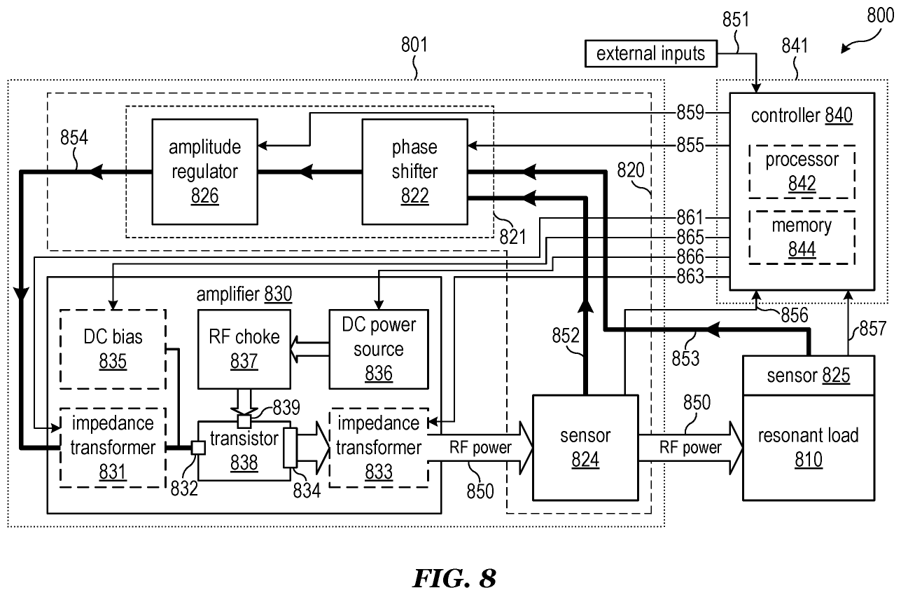

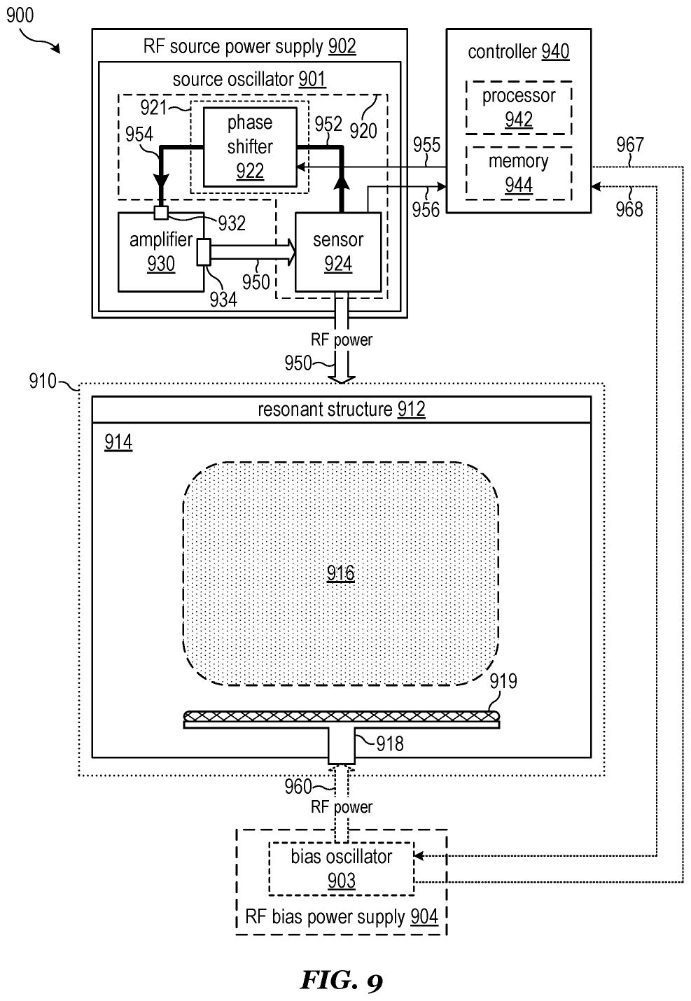

FIG. 8 illustrates an example RF system that includes a resonant oscillator circuit and a controller configured to send various control signals to components of an amplifier of the resonant oscillator circuit and to receive a sensor signal from a sensor of a feedback circuit of the resonant oscillator circuit in accordance with embodiments of the invention. The RF system of FIG. 8 may be a specific implementation of other RF systems described herein such as the RF system of FIG. 6, for example. Similarly labeled elements may be as previously described.

Referring to FIG. 8, an RF system 800 includes a resonant oscillator circuit 801 that includes a feedback circuit 820 and an amplifier 830. The resonant oscillator circuit 801 is configured to deliver RF power to a resonant load 810 from a power output 834 of the amplifier 830 using a first sensor 824 and a second sensor 825. The first sensor 824 is coupled to the RF power (transmission line 850) in such a way as to generate a first feedback signal 852. The second sensor 825 is coupled to the resonant load 810 (e.g., attached to a structure) so that a second feedback signal 853 is generated.

Feedback conditioning components 821, which include a phase shifter 822 and a amplitude regulator 826, modify one or more properties of the first feedback signal 852 and the second feedback signal 853 (e.g., a signal combined in the phase shifter 822) to generate a conditioned feedback signal 854, which is provided to a control input 832 of the amplifier 830. The amplifier 830 includes a transistor 838 with the control input 832 being the gate of the transistor 838. A DC power supply may be implemented as a DC power source 836 (such as a DC current source) coupled to a power input 839 of the transistor 838 through an RF choke 837. An optional DC bias 835 may be coupled to the control input 832 and facilitate control over the voltage at the control input 832.

The RF system 800 further includes a controller 840 that is configured to receive a sensor signal 856 from the first sensor 824 and a second sensor signal 857 from the second sensor 825 (and may receive addition sensor signals as well as external inputs 851, which may include various feedforward control information, such as process recipes, sequencing information, etc.) and control the phase shifter 822 using a phase control signal 855. The controller 840 may also be configured to control some or all of the other controllable elements included in the resonant oscillator circuit 801. For example, the amplitude regulator 826 may also be controlled by the controller 840 using an amplitude control signal 859. Additional RF measurements between signal points may also be included, such as phase measurements, gain measurements, and/or frequency measurements. For example, these signals can be used for controlling components such as the amplitude regulator 826, the phase shifter 822, the transistor 838, the first sensor 824, the second sensor 825, and so on.

Various additional controllable elements are shown as part of the amplifier 830 (some being optional). For example, the controller 840 may be configured to control an optional feedback impedance transformer 831 and an optional power impedance transformer 833 using a feedback impedance control signal 861 and a power impedance control signal 863, respectively. The optional feedback impedance transformer 831 and the optional power impedance transformer 833 are configured to adjust the impedance of the resonant oscillator circuit 801. In some cases, other changes to the RF waves passing through the transformers may occurs, such as changes to phase, which may contribute the overall character of the conditioned feedback signal 854. The impedance of the resonant oscillator circuit 801 may be adjusted by the optional feedback impedance transformer 831 and/or the optional power impedance transformer 833 for various reasons, including adjusting the input/output impedance experienced by the transistor 838 to desirable (e.g., optimal) values as the frequency changes, adjusting the phase contribution of the transformers themselves, and others. A bias control signal 865 may be used by the controller 840 to control the optional DC bias 835. Similarly, the controller 840 may be configured to control the DC power source 836 using a DC power control signal 866.

The controller 840 may include an optional processor 842 and/or an optional memory 844 (i.e., a non-transitory computer-readable medium) that stores a program including instructions that, when executed by the optional processor 842, control the phase shifter 822 and other controllable elements of the resonant oscillator circuit 801. For example, the optional memory 844 may have volatile memory (e.g., random access memory (RAM)) and non-volatile memory (e.g., flash memory). Alternatively, the program may be stored in physical memory at a remote location, such as in cloud storage. The optional processor 842 may be any suitable processor, such as the processor of a microcontroller, a general-purpose processor (such as a central processing unit (CPU), a microprocessor, a field-programmable gate array (FPGA), an application-specific integrated circuit (ASIC), and others.

FIG. 9 illustrates an example plasma system that includes a feedback circuit coupled to RF power delivered to a resonant load that includes a plasma chamber, an RF structure configured to generate a plasma in the plasma chamber using the RF power, and the plasma where the feedback circuit includes a phase shifter in accordance with embodiments of the invention. The plasma system of FIG. 9 may be a specific implementation of RF systems described herein such as the RF system of FIG. 6, for example. Similarly labeled elements may be as previously described.

Referring to FIG. 9, a plasma system 900 (such as a pulsed plasma system) includes a RF structure 912 that is configured to generate a plasma 916 in a plasma chamber 914 (e.g., to process a substrate 919 supported by a substrate support 918, such as a plasma etching chamber, a plasma deposition chamber, etc.) using RF power delivered to the RF structure 912 by an RF source power supply 902 through a source transmission line 950. The RF structure 912 may be any suitable structure, including antenna structures, electrode structures, waveguides, etc. The plasma system 900 is a pulsed plasma system in various embodiments, configured to deliver RF power to the RF structure 912 as a series of RF pulses at a desired pulse frequency, pulse width, and duty cycle.

The RF source power supply 902 includes a resonant oscillator circuit 901 that includes a feedback circuit 920 and an amplifier 930. The resonant oscillator circuit 901 is configured to deliver the RF power to a resonant load 910 (here including the RF structure 912, the plasma chamber 914, and the plasma 916, once it is generated). The RF power is delivered through the source transmission line 950 from a power output 934 of the amplifier 930 using a sensor 924 coupled to the RF power so that a feedback signal 952 is generated according to the RF power. Feedback conditioning components 921, including at least a phase shifter 922, modify one or more properties of the feedback signal 952 to generate a conditioned feedback signal 954, which is provided to a control input 932 of the amplifier 930.

A controller 940 (which may include an optional processor 942 and/or an optional memory 944) is configured to control the resonant oscillator circuit 901. For example, the controller 940 may control the phase shifter 922 using a phase control signal 955. The sensor 924 may send a sensor signal 956 indicating an attribute or state of the source transmission line 950 to the controller 940.

In some implementations, RF power may also be delivered to the substrate support 918 (often referred to as bias power) from an optional RF bias power supply 904 through a bias transmission line 960. The optional RF bias power supply 904 may also include an optional bias resonant oscillator circuit 903 that may be configured to adjust the phase of a feedback signal to efficiently couple the RF power to the substrate support 918. Specifically, the optional bias resonant oscillator circuit 903 may be similar to the resonant oscillator circuit 901 (also including a feedback circuit with a phase shifter and an amplifier). When included, the optional bias resonant oscillator circuit 903 may be controlled by the controller 940 using a bias phase control signal 967 (e.g., based on information received from at least one bias sensor signal 968).

FIG. 10 illustrates an example plasma system where the RF structure is implemented as an upper electrode of a capacitively coupled plasma (CCP) plasma system in accordance with embodiments of the invention. The CCP plasma system of FIG. 10 may be a specific implementation of other plasma systems described herein such as the plasma system of FIG. 9, for example. Similarly labeled elements may be as previously described.

Referring to FIG. 10, a CCP plasma system 1000 includes a UEL 1012 (an upper electrode, which may be a non-resonant structure) that is configured to generate a plasma 1016 in a plasma chamber 1014 (e.g., to process a substrate 1019 supported by a LEL 1018 (lower electrode that here is also a substrate support) using RF power delivered to the UEL 1012 by an RF source power supply 1002 through a source transmission line 1050, which may also include a power return structure, such as the outer conductor of a coaxial feed. The plasma chamber 1014 may be coupled to a ground potential 1046, which may be implemented as a reference potential that is configured to function as a substantially infinite charge sink in the context of the CCP plasma system 1000, or be earth ground, whether directly or indirectly). Further, the ground potential 1046 may be configured as a common return. The CCP plasma system 1000 is a pulsed plasma system in various embodiments.

The RF source power supply 1002 includes a resonant oscillator circuit 1001 configured to deliver the RF power to a resonant load 1010 (including the UEL 1012, the plasma chamber 1014, and the plasma 1016, once it is generated). An optional RF bias power supply 1004 may deliver RF power to the LEL 1018 through a bias transmission line 1060. The optional RF bias power supply 1004 may also include an optional bias resonant oscillator circuit 1003.

A controller 1040 (which may include an optional processor 1042 and/or an optional memory 1044) is configured to receive a source sensor signal 1056 from the resonant oscillator circuit 1001 and control the resonant oscillator circuit 1001 using a source phase control signal 1055. Similarly, the optional bias resonant oscillator circuit 1003 (when included) may be configured to receive a bias sensor signal 1068 and control the optional bias resonant oscillator circuit 1003 using a bias phase control signal 1067.

FIG. 11 illustrates an example plasma system where the RF structure is implemented as an RF antenna of an inductively coupled plasma (ICP) plasma system in accordance with embodiments of the invention. The ICP plasma system of FIG. 11 may be a specific implementation of other plasma systems described herein such as the plasma system of FIG. 9, for example. Similarly labeled elements may be as previously described.

Referring to FIG. 11, an ICP plasma system 1100 includes an RF antenna 1112 (e.g., a chamber antenna placed on or adjacent to a plasma chamber 1114 separated by a dielectric material 1148 allowing electromagnetic fields to penetrate into the plasma chamber 1114 from the RF antenna 1112) that is configured to generate a plasma 1116 in the plasma chamber 1114 (e.g., to process a substrate 1119 supported by a substrate support 1118 (lower electrode that here is also a substrate support) using RF power delivered to the RF antenna 1112 by an RF source power supply 1102 through a source transmission line 1150. For example, the RF antenna 1112 may be resonant structure like a resonant coil, such as a planar spiral coil, as shown (of course it could also be a helical coil or any one of many other types of resonant RF antenna structures). The plasma chamber 1114 may be coupled to a ground potential 1146. The ICP plasma system 1100 is a pulsed plasma system in various embodiments.

The RF source power supply 1102 includes a resonant oscillator circuit 1101 configured to deliver the RF power to a resonant load 1110 (including the RF antenna 1112, the plasma chamber 1114, and the plasma 1116, once it is generated). An optional RF bias power supply 1104 may deliver RF power to the substrate support 1118 through a bias transmission line 1160. The optional RF bias power supply 1104 may also include an optional bias resonant oscillator circuit 1103.

A controller 1140 (which may include an optional processor 1142 and/or an optional memory 1144) is configured to receive a source sensor signal 1156 from the resonant oscillator circuit 1101 and control the resonant oscillator circuit 1101 using a source phase control signal 1155. Similarly, the optional bias resonant oscillator circuit 1103 (when included) may be configured to receive a bias sensor signal 1168 and control the optional bias resonant oscillator circuit 1103 using a bias phase control signal 1167.

FIG. 12 illustrates an example method of adjusting the frequency of RF power applied to a resonant load in accordance with embodiments of the invention. The method of FIG. 12 may be combined with other methods and performed using the systems and apparatuses as described herein. For example, the method of FIG. 12 may be combined with any of the embodiments of FIGS. 1-11. Although shown in a logical order, the arrangement and numbering of the steps of FIG. 12 are not intended to be limited. The method steps of FIG. 12 may be performed in any suitable order or concurrently with one another as may be apparent to a person of skill in the art.

Referring to FIG. 12, a method 1200 of adjusting the frequency of RF power applied to a resonant load includes a step 1201 of generating RF power at a first frequency by supplying current to an amplifier of a resonant oscillator circuit. It should be understood that while the RF power is delivered at a first frequency, this is not necessarily a specific frequency value imposed on the resonant oscillator, but may instead be a function of the configuration of the circuit as a resonant circuit coupled to the resonant load. When current is supplied to the amplifier, the resonant oscillator circuit generates the RF power at a frequency (i.e., the first frequency). The RF power is delivered from a power output of the amplifier to a resonant load in step 1202 (e.g., substantially simultaneously with generation of the RF power in step 1201, but of course some small delay based on transmission implementation may be present). The resonant load has a resonant frequency.

In step 1203, a feedback signal is generated using the RF power. The feedback signal indicates a change in the resonant frequency to a second resonant frequency. Step 1204 includes adjusting the phase of the feedback signal to generate a conditioned feedback signal, which is applied to the control input to generate RF power at the second resonant frequency in step 1205. In this context “at” the second resonant frequency includes substantially similar frequencies, although the RF power generated in step 1205 may match the second resonant frequency exactly or nearly exactly in many cases.

Example embodiments of the invention are summarized here. Other embodiments can also be understood from the entirety of the specification as well as the claims filed herein.

Example 1. A resonant oscillator circuit including: an amplifier including a control input and a power output configured to deliver RF power to a resonant load; and a feedback circuit including a sensor coupled to the RF power and configured to generate a feedback signal using the RF power, and a phase shifter coupled between the control input and the sensor, the phase shifter being configured to adjust a phase of the feedback signal to provide a conditioned feedback signal at the control input.

Example 2. The resonant oscillator circuit of example 1, where the phase shifter is a fixed phase shifter.

Example 3. The resonant oscillator circuit of example 1, where the phase shifter is a variable phase shifter.

Example 4. The resonant oscillator circuit of one of examples 1 to 3, where the sensor is a current sensor, a voltage sensor, or a directional coupler.

Example 5. The resonant oscillator circuit of one of examples 1 to 4, where the feedback circuit further includes an amplitude regulator configured to adjust amplitude of the feedback signal to provide the conditioned feedback signal at the control input.

Example 6. The resonant oscillator circuit of one of examples 1 to 5, further including a controller operatively coupled to the sensor and the phase shifter, the controller being configured to control adjusting the phase of the feedback signal according to a sensor signal received from the sensor.

Example 7. The resonant oscillator circuit of example 4, where the resonant oscillator circuit is part of a pulsed plasma system configured to generate a plasma in a plasma chamber by pulsing the RF power to an RF structure, and where the resonant load includes the plasma, the plasma chamber, and the RF structure.

Example 8. The resonant oscillator circuit of one of examples 1 to 7, further including a DC bias coupled to the control input and configured to increase voltage at the control input to exceed a saturation threshold of the amplifier so that the amplifier operates as a class D amplifier.

Example 9. The resonant oscillator circuit of one of examples 1 to 8, further including an impedance transformer with flat frequency characteristics.

Example 10. An RF system including: a resonant oscillator circuit including an amplifier including a control input and a power output configured to deliver RF power to a resonant load, and a feedback circuit including a sensor coupled to the RF power and configured to generate a feedback signal using the RF power, and a phase shifter coupled between the control input and the sensor; and a controller operatively coupled to the sensor and the phase shifter, the controller being configured to control the phase shifter to adjust a phase of the feedback signal according to a sensor signal received from the sensor to provide a conditioned feedback signal at the control input.

Example 11. The RF system of example 10, where the phase of the feedback signal is adjusted at a timescale of tens of microseconds or less.

Example 12. The RF system of one of examples 10 and 11, where the phase shifter is an analog phase shifter, and where the controller is configured to set operating parameters of the analog phase shifter using digital elements.

Example 13. The RF system of one of examples 10 to 12, where the feedback circuit further includes an amplitude regulator operatively coupled to the controller, and where the controller is further configured to control the amplitude regulator to adjust amplitude of the feedback signal according to the sensor signal to provide the conditioned feedback signal at the control input.

Example 14. The RF system of one of examples 10 to 13, further including an impedance transformer operatively coupled to the controller, where the controller is further configured to control the impedance transformer to adjust impedance of the resonant oscillator circuit according to the sensor signal.

Example 15. The RF system of one of examples 10 to 14, where the amplifier further includes: a transistor including the control input, the power output, and a power input; and a DC power supply electrically coupled to the power input through an RF choke, the controller being further configured to control the DC power supply to provide DC power at the power input.

Example 16. A plasma system including: a plasma chamber; an RF structure configured to generate a plasma in the plasma chamber using RF power; a resonant load including the RF structure, the plasma chamber, and the plasma; a transistor including a control input, a power input, and a power output configured to deliver the RF power to the resonant load; a DC power supply coupled to the power input of the transistor; and a feedback circuit including a sensor coupled to the RF power and configured to generate a feedback signal using the RF power, and a phase shifter coupled between the control input and the sensor, the phase shifter being configured to adjust a phase of the feedback signal to provide a conditioned feedback signal at the control input.

Example 17. The plasma system of example 16, further including: a controller operatively coupled to the DC power supply, the sensor, and the phase shifter, the controller being configured to control the phase shifter to adjust the phase of the feedback signal according to a sensor signal received from the sensor, and control the DC power supply to provide DC power at the power input of the transistor.

Example 18. The plasma system of one of examples 16 and 17, where the sensor is coupled in series with a transmission line between the power output of the transistor and the resonant load.

Example 19. The plasma system of one of examples 16 and 17, where the sensor is attached to the plasma chamber.

Example 20. The plasma system of one of examples 16 to 19, where the plasma system is a pulsed plasma system configured to generate the plasma in the plasma chamber by pulsing the RF power to the RF structure.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A resonant oscillator circuit comprising:
an amplifier comprising a control input and a power output configured to deliver RF power to a resonant load; and
a feedback circuit comprising
a sensor coupled to the RF power and configured to generate a feedback signal using the RF power, and
a phase shifter coupled between the control input and the sensor, the phase shifter being configured to adjust a phase of the feedback signal to provide a conditioned feedback signal at the control input.

2. The resonant oscillator circuit of claim 1, wherein the phase shifter is a fixed phase shifter.

3. The resonant oscillator circuit of claim 1, wherein the phase shifter is a variable phase shifter.

4. The resonant oscillator circuit of claim 1, wherein the sensor is a current sensor, a voltage sensor, or a directional coupler.

5. The resonant oscillator circuit of claim 1, wherein the feedback circuit further comprises an amplitude regulator configured to adjust amplitude of the feedback signal to provide the conditioned feedback signal at the control input.

6. The resonant oscillator circuit of claim 1, further comprising a controller operatively coupled to the sensor and the phase shifter, the controller being configured to control adjusting the phase of the feedback signal according to a sensor signal received from the sensor.

7. The resonant oscillator circuit of claim 4, wherein the resonant oscillator circuit is part of a pulsed plasma system configured to generate a plasma in a plasma chamber by pulsing the RF power to an RF structure, and wherein the resonant load comprises the plasma, the plasma chamber, and the RF structure.

8. The resonant oscillator circuit of claim 1, further comprising a direct current (DC) bias coupled to the control input and configured to increase voltage at the control input to exceed a saturation threshold of the amplifier so that the amplifier operates as a class D amplifier.

9. The resonant oscillator circuit of claim 1, further comprising an impedance transformer with flat frequency characteristics.

10. A radio frequency (RF) system comprising:
a resonant oscillator circuit comprising
an amplifier comprising a control input and a power output configured to deliver RF power to a resonant load, and
a feedback circuit comprising
a sensor coupled to the RF power and configured to generate a feedback signal using the RF power, and
a phase shifter coupled between the control input and the sensor; and
a controller operatively coupled to the sensor and the phase shifter, the controller being configured to control the phase shifter to adjust a phase of the feedback signal according to a sensor signal received from the sensor to provide a conditioned feedback signal at the control input.

11. The RF system of claim 10, wherein the phase of the feedback signal is adjusted at a timescale of tens of microseconds or less.

12. The RF system of claim 10, wherein the phase shifter is an analog phase shifter, and wherein the controller is configured to set operating parameters of the analog phase shifter using digital elements.

13. The RF system of claim 10, wherein the feedback circuit further comprises an amplitude regulator operatively coupled to the controller, and wherein the controller is further configured to control the amplitude regulator to adjust amplitude of the feedback signal according to the sensor signal to provide the conditioned feedback signal at the control input.

14. The RF system of claim 10, further comprising an impedance transformer operatively coupled to the controller, wherein the controller is further configured to control the impedance transformer to adjust impedance of the resonant oscillator circuit according to the sensor signal.

15. The RF system of claim 10, wherein the amplifier further comprises:
a transistor comprising the control input, the power output, and a power input; and
a direct current (DC) power supply electrically coupled to the power input through an RF choke, the controller being further configured to control the DC power supply to provide DC power at the power input.

16. A plasma system comprising:
a plasma chamber;
a radio frequency (RF) structure configured to generate a plasma in the plasma chamber using RF power;
a resonant load comprising the RF structure, the plasma chamber, and the plasma;
a transistor comprising a control input, a power input, and a power output configured to deliver the RF power to the resonant load;
a direct current (DC) power supply coupled to the power input of the transistor; and
a feedback circuit comprising
a sensor coupled to the RF power and configured to generate a feedback signal using the RF power, and
a phase shifter coupled between the control input and the sensor, the phase shifter being configured to adjust a phase of the feedback signal to provide a conditioned feedback signal at the control input.

17. The plasma system of claim 16, further comprising:
a controller operatively coupled to the DC power supply, the sensor, and the phase shifter, the controller being configured to
control the phase shifter to adjust the phase of the feedback signal according to a sensor signal received from the sensor, and
control the DC power supply to provide DC power at the power input of the transistor.

18. The plasma system of claim 16, wherein the sensor is coupled in series with a transmission line between the power output of the transistor and the resonant load.

19. The plasma system of claim 16, wherein the sensor is attached to the plasma chamber.

20. The plasma system of claim 16, wherein the plasma system is a pulsed plasma system configured to generate the plasma in the plasma chamber by pulsing the RF power to the RF structure.
